(19) United States
(12) Patent Application Publication
(10) Pub. No.: US 2026/0271654 A1
(43) Pub. Date: Sep. 10, 2026

(54) VERTICAL HEAT TREATMENT DEVICE

(71) Applicant: Changzhou S.C Exact Equipment Co., Ltd., Changzhou City (CN)

(72) Inventors: Jingdian TAN, Changzhou City (CN); Jinsheng Deng, Changzhou City (CN); Bin Luo, Changzhou City (CN); Yaping Peng, Changzhou City (CN)

(21) Appl. No.: 19/661,977

(22) Filed: Apr. 29, 2026

Related U.S. Application Data
(63) Continuation of application No. PCT/CN2025/099370, filed on Jun. 5, 2025.

(30) Foreign Application Priority Data
Aug. 9, 2024 (CN) 202411094126.X

(51) Int. Cl. H10P 72/00; F27B 9/14; F27B 9/38; F27D 3/00; H10P 72/10

(52) U.S. Cl. CPC H10P 72/0434; F27B 9/142; F27B 9/38; F27D 3/0084; H10P 72/12; F27B 2009/382; F27B 2009/384; F27B 2009/386; F27D 2003/0075

(57) ABSTRACT

The present invention discloses a vertical heat treatment device, which includes a vertical furnace, a temporary storage and cooling portion, and a segmented loading and unloading structure. The segmented loading and unloading structure is provided with a first-stage conveying device and a first-stage conveying device; the first-stage conveying device is positioned below the vertical furnace and configured to convey a vertical boat into or out of the vertical furnace; and the first-stage conveying device is configured to transfer the vertical boat between the temporary storage and cooling portion and the first-stage conveying device.

### CROSS-REFERENCE TO RELATED PATENT APPLICATION

This application is a continuation application of International Patent Application No. PCT/CN2025/099370, filed on Jun. 5, 2025, which itself claims priority to Chinese Patent Application No. CN 202411094126.X filed in China on Aug. 9, 2024. The disclosures of the above applications are incorporated herein in their entireties by reference.

### FIELD OF THE PRESENT INVENTION

The present invention belongs to the field of solar photovoltaic cell production devices, and particularly relates to a vertical heat treatment device.

### BACKGROUND OF THE PRESENT INVENTION

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure. [0004] With the continuous increase in global demand for renewable energy, solar photovoltaic industry has developed rapidly. Vertical furnace devices can be configured to carry out specific processes on silicon wafers such as coating, diffusion, oxidation, and thin-film deposition.

In an existing vertical furnace, a method for directly driving with a single conveying device is usually utilized to convey and hoist vertical boats. For example, in patent document CN114203611 A, a quartz boat handling device is configured to transfer a quartz boat among a buffer rack, a reaction chamber, and a boat-turning device; specifically, the quartz boat handling device includes a moving rail assembly, a manipulator, and a clamping assembly, in which, the clamping assembly is connected to the manipulator, the manipulator is mounted on the moving rail assembly, the moving rail assembly is configured to drive the manipulator to move back and forth along the moving rail assembly to transfer the quartz boat among the buffer rack, the reaction chamber, and the boat-turning device, and the clamping assembly is configured to clamp the quartz boat. This method is long in conveying stroke, which makes the device to carry out load-bearing operations for a long time, resulting in its deformation, and moreover, the long stroke also imposes higher requirements on device space and brings great inconvenience to the operation and maintenance by the staff.

### SUMMARY OF THE INVENTION

An objective of the present invention is to provide a vertical heat treatment device, which realizes segmented loading and unloading; and a conveying device at each stage has a short conveying stroke, which makes it to complete operations within a relatively short time, thereby reducing the requirement for strength, reducing deformation, as well as helping to increase the utilization rate of device space.

In order to achieve above objective, the following technical solution is adopted in the present invention:
the provided vertical heat treatment device includes: a vertical furnace, a temporary storage and cooling portion, and a segmented loading and unloading structure, in which, the segmented loading and unloading structure is provided with a first-stage conveying device and a first-stage conveying device;
the first-stage conveying device is positioned below the vertical furnace and configured to convey a vertical boat into or out of the vertical furnace; and the first-stage conveying device is configured to transfer the vertical boat between the temporary storage and cooling portion and the first-stage conveying device.

Further, the first-stage conveying device includes:
a first horizontal guide rail which is positioned below the vertical furnace, with one end positioned in boat transfer areas of the first-stage conveying device and the first-stage conveying device;
a first supporting component which is slidably arranged on the first horizontal guide rail and configured to support the vertical boat;
a first drive component which is configured to drive the first supporting component to move on the first horizontal guide rail; and
a jacking moving component which is connected to the first horizontal guide rail and configured to drive the first horizontal guide rail and the first supporting component to move in a vertical direction to convey the vertical boat into or out of the vertical furnace.

Further, the second-stage conveying device includes:
a first lifting guide rail which is positioned on one side of the vertical furnace, with one end positioned in the boat transfer areas of the second-stage conveying device and the first-stage conveying device;
a first manipulator structure which is slidably arranged on the first lifting guide rail and is provided with a first hanging component and a horizontal moving component, the first hanging component being arranged on the horizontal moving component and configured to hang the vertical boat, and the horizontal moving component being configured to drive the first hanging component to move in a horizontal direction to convey the vertical boat into or out of the temporary storage and cooling portion; and
a second drive component which is configured to drive the first manipulator structure to move on the first lifting guide rail.

Further, the first-stage conveying device includes:
a second manipulator structure that is provided with a first-stage conveying component and a second-stage conveying component which are vertically arranged, a boat conveying path of the first-stage conveying component in the vertical direction being at least partially overlapped with the boat conveying path of the second-stage conveying component, the first-stage conveying component and the second-stage conveying component being matched to convey the vertical boat in sections in the vertical direction so as to convey the vertical boat into or out of the vertical furnace; and
a moving platform which is connected to the second-stage conveying component and configured to drive the second-stage conveying component to move in the horizontal direction so as to transfer the vertical boat between the second-stage conveying component and the second-stage conveying device.

Further, the first-stage conveying component includes:
a second lifting guide rail which is arranged below the vertical furnace and is positioned on one side of the second-stage conveying component;
a lifting support frame which is slidably arranged on the second lifting guide rail;
a second horizontal guide rail which is arranged on the lifting support frame;
a second support component which is slidably arranged on the second horizontal guide rail and configured to support the vertical boat;
a third drive component which is configured to drive the lifting support frame to move on the second lifting guide rail to convey the vertical boat into or out of the vertical furnace; and
a fourth drive component which is configured to drive the second support component to move on the second horizontal guide rail so as to bear the vertical boat on the second-stage conveying component or transfer the vertical boat to the second-stage conveying component.

Further, the second-stage conveying component includes:
a third lifting guide rail which is arranged below the vertical furnace and is lower than the second lifting guide rail in the vertical direction;
a second hanging component which is slidably arranged on the third lifting guide rail and configured to hang the vertical boat; and
a fifth drive component which is configured to drive the second hanging component to move on the third lifting guide rail.

Further, the second-stage conveying device includes a boat-in conveying channel and a boat-out conveying channel which are arranged in parallel and are opposite in conveying directions, and part of the conveying paths of the boat-in conveying channel and the boat-out conveying channel correspond to the temporary storage and cooling portion;
the moving platform is arranged between the boat-in conveying channel and the boat-out conveying channel and is configured to drive the second-stage conveying component to move in the horizontal direction so as to transfer the vertical boat among the second-stage conveying component, the boat-in conveying channel, and the boat-out conveying channel.

Further, the vertical furnace includes an outer furnace body, an inner furnace body, and a lower furnace door which define a heating chamber, and a boat support frame for hanging a plurality of vertical boats is arranged in the heating chamber.

Further, the vertical furnace further includes a rotary chuck and a sixth drive component which are arranged on the lower furnace door, and the sixth drive component is connected to the rotary chuck and configured to drive the whole vertical furnace to rotate so as to make part of hanging positions on the boat support frame corresponding to the first-stage conveying device.

Further, the segmented loading and unloading structure is capable of conveying two vertical boats each time.

Compared with the prior art, the vertical heat treatment device provided by the present invention has the beneficial effects that the segmented loading and unloading structure is arranged in the vertical heat treatment device, such that the problem of overlong stroke caused by loading and unloading directly by a single conveying device can be avoided, and the conveying device at each stage is relatively short in conveying stroke, which makes it to complete operations within a relatively short time, thereby reducing the requirement for strength, reducing deformation, as well as helping to increase the utilization rate of device space.

### BRIEF DESCRIPTION OF THE DRAWINGS

In order to more clearly illustrate the technical solutions in the embodiments of the present invention, the accompanying drawings required for use in the description of the embodiments or the prior art will be briefly introduced below. Obviously, the accompanying drawings described below only show some embodiments of the present invention, and for those of ordinary skill in the art, other drawings can also be obtained based on these accompanying drawings without any inventive effort.

FIG. 1 is a front schematic view of a vertical heat treatment device provided in an Embodiment 1 of the present invention;

FIG. 2 is a top schematic view of a vertical heat treatment device provided in an Embodiment 1 of the present invention;

FIG. 3 is a left schematic view of a vertical heat treatment device provided in an Embodiment 1 of the present invention;

FIG. 4 is a sectional schematic view of a vertical furnace provided in an Embodiment 1 of the present invention;

FIG. 5 is a top schematic view of a vertical heat treatment device provided in an Embodiment 2 of the present invention;

FIG. 6 is a sectional schematic view in an A-A direction in FIG. 5;

FIG. 7 is a top schematic view of a belt conveying mechanism and a temporary storage and cooling portion provided in an Embodiment 2 of the present invention;

FIG. 8 is a sectional schematic view of a first-stage conveying device provided in an Embodiment 2 of the present invention; and

FIG. 9 is a sectional schematic view of a vertical furnace provided in an Embodiment 2 of the present invention.

### REFERENCE NUMERALS

1, vertical furnace; 2, temporary storage and cooling portion; 3, first-stage conveying device; 4, second-stage conveying device; 5, vertical boat; 6, wafer inserting mechanism; 11, outer furnace; 12, inner furnace; 13, lower furnace door; 14, rotary chuck; 15, seventh drive component;
31, first horizontal guide rail; 32, first supporting component;
41, first lifting guide rail; 42, first manipulator structure;
421, first hanging component; 4211, first hanging hook; 422, horizontal moving component;
35, first-stage conveying component; 36, second-stage conveying component;
351, second lifting guide rail; 352, lifting support frame; 353, second horizontal guide rail; 354, second supporting component; 3541, hanging frame; 3542, hook;
361, third lifting guide rail; 362, second hanging component; 3621, second hanging hook;
47, boat-in conveying channel; 48, boat-out conveying channel;
471, belt conveying mechanism; and
51, second boat support frame.

### DETAILED DESCRIPTION OF SOME EMBODIMENTS

In order to make the technical problems, technical solutions, and beneficial effects to be solved by the present invention clearer, the present invention is further described in detail below in conjunction with the accompanying drawings and embodiments. It is to be understood that the specific embodiments described herein are only configured to explaining the present invention and are not intended to limit the present invention.

The present invention provides a novel vertical heat treatment device, which realizes segmented loading and unloading; and a conveying device at each stage has a short conveying stroke, which makes it to complete operations within a relatively short time, thereby reducing the requirement for strength, reducing deformation, as well as helping to increase the utilization rate of device space.

### Embodiment 1

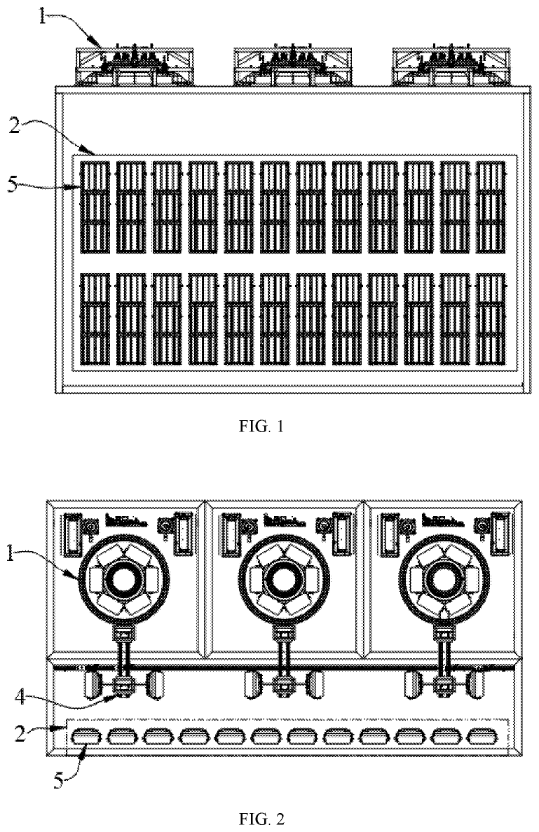

With reference to FIG. 1 to FIG. 4, a vertical heat treatment device provided in this embodiment mainly includes vertical furnaces 1, temporary storage and cooling portions 2, and segmented loading and unloading structures. The segmented loading and unloading structures are configured to transfer vertical boats 5 between the vertical furnaces 1 and the temporary storage and cooling portions 2. In addition, the vertical heat treatment device further includes electrical elements such as a pump.

As shown in FIG. 3, a plurality of vertical furnaces 1 are arranged at intervals on an upper left portion of the whole device, and the temporary storage and cooling portions 2 are arranged on the rightmost side of the whole device and provided with a plurality of boat storage positions.

It is to be understood that the number of the vertical furnaces 1 and the number of the boat storage positions in the temporary storage and cooling portions 2 can be flexibly set according to actual requirements. By way of an example, there are 3 vertical furnaces 1 arranged in the vertical heat treatment device, and 24 boat storage positions are arranged in an upper row and a lower row in the temporary storage and cooling portions 2.

It is also to be understood that the segmented loading and unloading structures correspond to the vertical furnaces 1 one to one. One vertical furnace 1 and the corresponding segmented loading and unloading structure are taken as an example for describing in detail below.

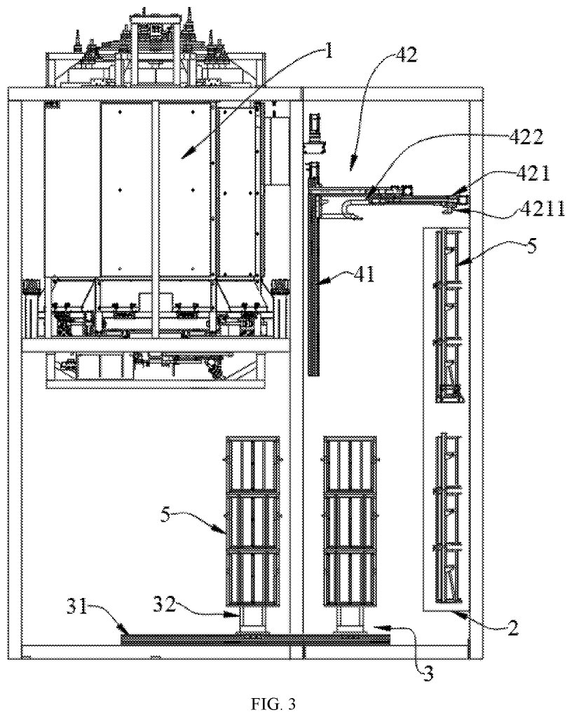

As shown in FIG. 2 and FIG. 3, the segmented loading and unloading structure is provided with a first-stage conveying device 3 and a second-stage conveying device 4. The first-stage conveying device 3 is positioned below the vertical furnace 1 and configured to convey the vertical boat 5 into or out of the vertical furnace 1; and the second-stage conveying device 4 is conveyed to transfer the vertical boat 5 between the temporary storage and cooling portion 2 and the first-stage conveying device 3.

It is to be understood that the second-stage conveying device 4 and the first-stage conveying device 3 are matched to achieve segmented conveying of the vertical boat 5, and a position in which the second-stage conveying device 4 and the first-stage conveying device 3 are matched to transfer the vertical boat 5 is called as a boat transfer area below.

As shown in FIG. 3, the first-stage conveying device 3 at least includes a first horizontal guide rail 31, a first supporting component 32, a first drive component, and a jacking moving component.

The first horizontal guide rail 31 is positioned below the vertical furnace 1, with one end positioned in the boat transfer area; the first supporting component 32 is slidably arranged on the first horizontal guide rail 31 and configured to support the vertical boat 5; the first drive component is configured to drive the first supporting components 32 to move on the first horizontal guide rail 31; and the jacking moving component is connected to the first horizontal guide rail 31 and configured to drive the first horizontal guide rail 31 and the first supporting components 32 to move in the vertical direction to convey the vertical boat 5 into or out of the vertical furnace 1.

In the first-stage conveying device 3, the first drive component is subjected to a motor drive mode or a cylinder drive mode and is capable of driving the first supporting components 32 to move left and right along the first horizontal guide rail 31.

In the first-stage conveying device 3, the jacking moving component can also be subjected to the motor drive mode or the cylinder drive mode and is capable of driving the first horizontal guide rail 31 and the first supporting component 32 thereon to move up and down in the vertical direction.

In the first-stage conveying device 3, the first supporting component 32 can be a support frame and the like, such that the weight can be reduced while enough bearing capacity is guaranteed, and there are preferably two first supporting components 32.

As shown in FIG. 3, the second-stage conveying device 4 at least includes a first lifting guide rail 41, a first manipulator structure 42, and a second drive component.

The first lifting guide rail 41 is positioned on one side of the vertical furnace 1, with one end positioned in the boat transfer area; the first manipulator structure 42 is slidably arranged on the first lifting guide rail 41; and the second drive component is configured to drive the first manipulator structure 42 to move on the first lifting guide rail 41.

In the second-stage conveying device 4, the second drive component can be subjected to the motor drive mode or the cylinder drive mode and is capable of driving the first manipulator structure 42 to move up and down along the first lifting guide rail 41.

In the second-stage conveying device 4, the first manipulator structure 42 is provided with first hanging components 421 and a horizontal moving component 422; the first hanging components 421 are arranged on the horizontal moving component 422 and configured to hang the vertical boat 5; and the horizontal moving component 422 is configured to drive the first hanging components 421 to move in the horizontal direction to convey the vertical boat 5 into or out of the temporary storage and cooling portion 2.

In the first manipulator structure 42, two first hanging components 421 are provided and are symmetrically arranged on both sides of the horizontal moving component 422 for achieving conveying of two vertical boats 5 each time. The horizontal moving component 422 can be of a belt conveying structure; and the first hanging components 421 are provided with first hanging hooks 4211 capable of opening and closing to realize supporting or separation of the vertical boat 5. It is to be understood that if two vertical boats 5 are conveyed by the first manipulator structure 42 each time, two first-stage conveying devices 3 are to be provided, and the two first-stage conveying devices 3 are arranged in parallel for synchronous operation.

In this embodiment, the cross section profile of the vertical boat 5 can be square or rectangular. If the cross section profile of the vertical boat 5 is rectangular, and the direction of the vertical boat 5 placed in the temporary storage and cooling portion 2 is not consistent with the directions thereof in the vertical furnace 1, the segmented loading and unloading structure further includes a boat rotating device for rotating the vertical boat 5 by 90°; and after being rotated with the boat rotating device, the vertical boat 5 will be conveyed to the second-stage conveying device 4 or placed in the temporary storage and cooling portion 2, thereby ensuring that the vertical boat 5 can be smoothly conveyed into the vertical furnace 1 or the temporary storage and cooling portion 2.

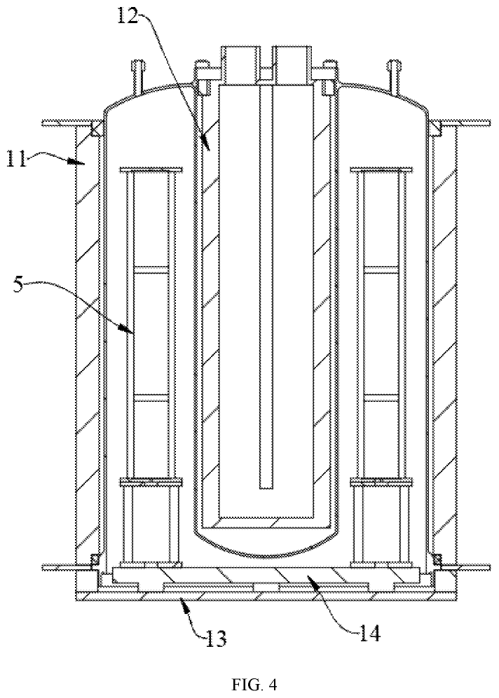

As shown in FIG. 4, the vertical furnace 1 includes an outer furnace 11, an inner furnace 12, and a lower furnace door 13 which define a heating chamber.

An upper end of the outer furnace 11 is closed while a lower end thereof is opened; the upper end of the inner furnace 12 is opened while the lower end thereof is closed; and the lower furnace door 13 is detachably arranged at the lower end of the outer furnace 11. Heating sources are arranged on the outer furnace 11 and the inner furnace 12, and the heating sources can be heating wires, infrared lamp tubes, electromagnetic induction heating, etc.

A first support frame configured to hang a plurality of vertical boats 5 is arranged in the heating chamber and sleeves an outer side of the inner furnace 12; a plurality of hanging positions are annularly arranged on the first support frame, and each hanging position is in clamped connection with a clamping member on the corresponding vertical boat 5.

The vertical furnace 1 further includes a rotary chuck 14 and a sixth drive component; the rotary chuck 14 is arranged on the lower furnace door 13, and the sixth drive component is connected to the rotary chuck 14; the sixth drive component is configured to drive the rotary chuck 14 to rotate so as to drive the whole vertical furnace 1 to rotate to make part of the hanging positions on the first support frame corresponding to the first-stage conveying device 3, thereby facilitating transferring of the vertical boat 5 between the vertical furnace 1 and the first-stage conveying device 3, and improving the conveying efficiency. A guide plate can be arranged on the rotary chuck 14 and can make the rotating direction of the rotary chuck more stable and consistent.

In the vertical heat treatment device provided by the present invention, the segmented loading and unloading structure is arranged, such that the problem of overlong stroke caused by loading and unloading directly by a single conveying device can be avoided, and the conveying device at each stage is relatively short in conveying stroke, which makes it to complete operations within a relatively short time, thereby reducing the requirement for strength, reducing deformation, as well as helping to increase the utilization rate of device space.

### Embodiment 2

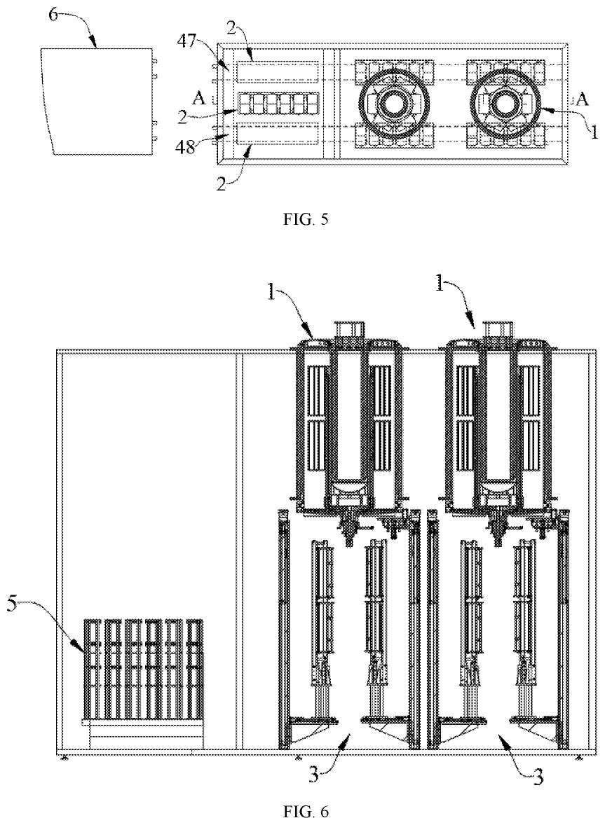

With reference to FIG. 5, a vertical heat treatment device provided in this embodiment mainly includes vertical furnaces 1, temporary storage and cooling portions 2, and segmented loading and unloading structures. The segmented loading and unloading structures are configured to transfer vertical boats 5 between the vertical furnaces 1 and the temporary storage and cooling portions 2. In addition, the vertical heat treatment device further includes electrical elements such as a pump.

As shown in FIG. 6, a plurality of vertical furnaces 1 are arranged at intervals on an upper right portion of the whole device, and the temporary storage and cooling portions 2 are arranged on the lower left portion and/or upper left portion of the whole device and provided with a plurality of boat storage positions.

It is to be understood that the number of the vertical furnaces 1 and the number of the boat storage positions in the temporary storage and cooling portions 2 can be flexibly set according to actual requirements. By way of an example, two vertical furnaces 1 are arranged in the vertical heat treatment device, and the number of the boat storage positions in the temporary storage and cooling portion 2 is a multiple of six.

It is also to be understood that although the plurality of vertical furnaces 1 are arranged, they share the segmented loading and unloading structure.

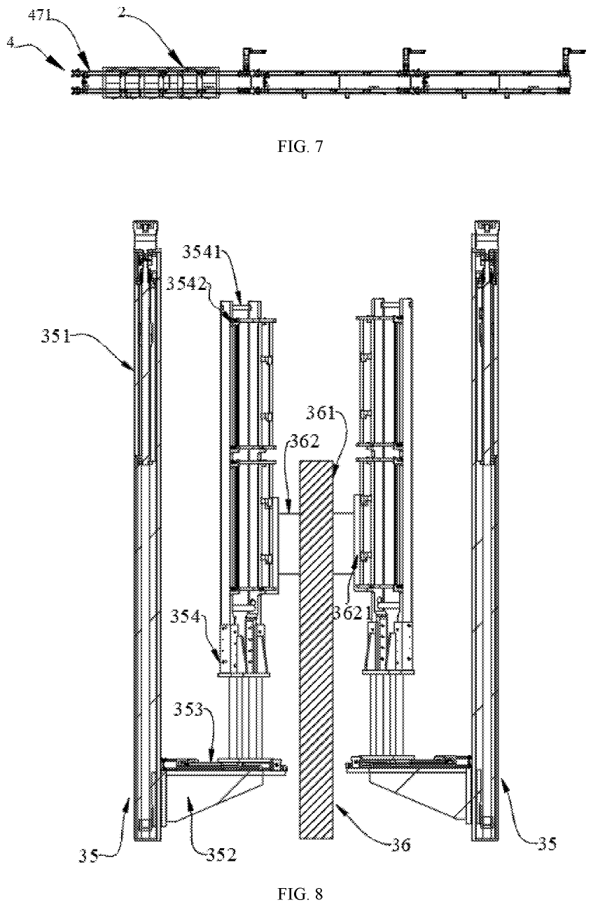

As shown in FIG. 6 and FIG. 7, the segmented loading and unloading structure is provided with a first-stage conveying device 3 and a second-stage conveying device 4. The first-stage conveying device 3 is positioned below the vertical furnaces 1 and configured to convey the vertical boat 5 into or out of the vertical furnaces 1; and the second-stage conveying device 4 is conveyed to transfer the vertical boats 5 between the temporary storage and cooling portion 2 and the first-stage conveying device 3.

As shown in FIG. 8, the first section conveying device 3 at least includes a second mechanical arm structure and a moving platform.

The second manipulator structure is provided with first-stage conveying components 35 and a second-stage conveying component 36 which are vertically arranged; boat conveying paths of the first-stage conveying components 35 in the vertical direction are at least partially overlapped with the boat conveying path of the second-stage conveying component 36; the first-stage conveying components 35 and the second-stage conveying component 36 are matched to convey the vertical boats 5 in sections in the vertical direction so as to convey the vertical boats 5 into or out of the vertical furnaces 1.

The moving platform is connected to the second-stage conveying component 36 and configured to drive the second-stage conveying component 36 to move in the horizontal direction so as to transfer the vertical boats 5 between the second-stage conveying component 36 and the second-stage conveying device 4.

In this embodiment, the whole stroke of the first-stage conveying device 3 is divided into a plurality of short strokes, and meanwhile, the whole space is more compact, such that the conveying efficiency is improved, while the utilization of the device space is improved.

As shown in FIG. 8, there are two first-stage conveying components 35 and one second-stage conveying component 3 in the first-stage conveying device 3, and the two first-stage conveying components 35 are symmetrically arranged on both sides of the second-stage conveying component 36 so as to convey two vertical boats 5 each time.

Taking one first-stage conveying component 35 as an example, the first-stage conveying component 35 at least includes: a second lifting guide rail 351, a lifting support frame 352, a second horizontal guide rail 353, a second supporting component 354, a third drive component, and a fourth drive component.

The second lifting guide rail 351 is arranged below the vertical furnace 1 and is positioned on one side of the second-stage conveying component 36; the lifting support frame 352 is slidably arranged on the second lifting guide rail 351; the second horizontal guide rail 353 is arranged on the lifting support frame 352; the second support component 354 is slidably arranged on the second horizontal guide rail 353 and configured to support the vertical boats 5; the third drive component is configured to drive the lifting support frame 352 to move on the second lifting guide rail 351 to convey the vertical boat 5 into or out of the vertical furnace 1; and the fourth drive component is configured to drive the second support component 354 to move on the second horizontal guide rail 353 so as to bear the vertical boats 5 on the second-stage conveying component 36 or transfer the vertical boats 5 to the second-stage conveying component 36.

In the first-stage conveying component 35, the third drive component can be subjected to a motor drive mode or a cylinder drive mode and is capable of driving the lifting support frame 352 to move up and down along the second lifting guide rail 351.

In the first-stage conveying component 35, the fourth drive component can be subjected to the motor drive mode or the cylinder drive mode and is capable of driving the second support component 354 to move left and right along the second horizontal guide rail 353.

In the first-stage conveying component 35, the second support component 354 is provided with a bottom base and a hanging frame 3541 which is vertically arranged on the bottom base, and the hanging frame 3541 is provided with a plurality of hooks 3542 for hanging one vertical boat 5 together.

As shown in FIG. 8, the second-stage conveying component 36 at least includes: a third lifting guide rail 361, a second hanging component 362, and a fifth drive component.

The third lifting guide rail 361 is arranged below the vertical furnace 1 and is lower than the second lifting guide rail 351 in the vertical direction; the second hanging component 362 is slidably arranged on the third lifting guide rail 361 and configured to hang the vertical boats 5; and the fifth drive component is configured to drive the vertical boats 5 to move on the third lifting guide rail 361.

In the second-stage conveying component 36, the fifth drive component can be a linear motor assembly, and the second hanging component 362 is mounted on a slider in the linear motor assembly.

In the second-stage conveying component 36, the second hanging component 362 includes two second hanging hooks 3621 which are symmetrically arranged. Taking one hanging hook as an example, a side portion of the hanging hook is provided with a slot which is in clamped connection with a clamping member on each vertical boat 5, and a lower end of the hanging hook is provided with a supporting extension portion for supporting a bottom portion of each vertical boat 5.

As shown in FIG. 5 and FIG. 7, the second-stage conveying device 4 includes a boat-in conveying channel 47 and a boat-out conveying channel 48 which are arranged in parallel and are opposite in conveying directions, and part of conveying paths of the boat-in conveying channel 47 and the boat-out conveying channel 48 correspond to the temporary storage and cooling portion 2.

It is to be understood that belt conveying mechanisms 471 are arranged in the boat-in conveying channel 47 and the boat-out conveying channel 48 and are configured to convey the vertical boats 5.

The vertical heat treatment device further includes a wafer inserting mechanism 6 which is arranged on the leftmost side of the whole device, and the vertical boat 5 subjected to wafer inserting can be directly placed on the belt conveying mechanism 471 in the boat-in conveying channel 47 and then is conveyed to a designated position through the belt conveying mechanism 471.

It is also to be understood that the moving platform in the first-stage conveying device 3 is arranged between the boat-in conveying channel 47 and the boat-out conveying channel 48 and is configured to drive the second-stage conveying component 36 to move in the horizontal direction so as to transfer the vertical boats 5 among the second-stage conveying component 36, the boat-in conveying channel 47, and the boat-out conveying channel 48. The moving platform can drive the second-stage conveying component 36 to move in a motor or cylinder drive mode.

In order to better understand, the second-stage conveying device 4 provided in this the embodiment is further described below:
the second-stage conveying device 4 includes the boat-in conveying channel 47 and the boat-out conveying channel 48, and an inlet of the boat-in conveying channel 47 and an outlet of the boat-out conveying channel 48 are in the same side of the whole device. Although the boat-in conveying channel 47 and the boat-out conveying channel 48 are opposite in the conveying directions, they utilize the belt conveying mechanisms 471 of the same structure to convey the vertical boats 5.

The belt conveying mechanism 471 in the boat-in conveying channel 47 is taken as an example for describing below: the belt conveying mechanism 471 includes a first conveying belt, a second conveying belt, and a third conveying belt which are sequentially connected end to end; the first conveying belt corresponds to the temporary storage and cooling portion 2; and each of the second conveying belt and the third conveying belt corresponds to one vertical furnace 1. The first conveying belt, the second conveying belt, and the third conveying belt can be independently controlled to start or stop.

In practical application, the vertical boats 5 are conveyed in groups, and each group of vertical boats 5 may include six vertical boats 5. The first conveying belt, the second conveying belt, and the third conveying belt are synchronously started, firstly one group of vertical boats 5 can be conveyed to the third conveying belt, the third conveying belt is stopped, then another group of vertical boats 5 can be conveyed to the second conveying belt, and the second conveying belt and the first conveying belt are stopped. In the subsequent process that two vertical boats 5 are conveyed into the vertical furnaces 1 through the first-stage conveying device 3 each time, if two vertical boats 5 are conveyed by the second-stage conveying component 36 at the time, the second conveying belt or the third conveying belt will be controlled to move by a preset distance so that the second-stage conveying component 36 can pick up the vertical boat 5 next time.

Definitely, an additional boat carrying device can be further arranged and configured to transfer the vertical boats 5 from the temporary storage and cooling portion 2 to the boat-in conveying channel 47 and transfer the vertical boats 5 from the boat-out conveying channel 48 to the temporary storage and cooling portion 2.

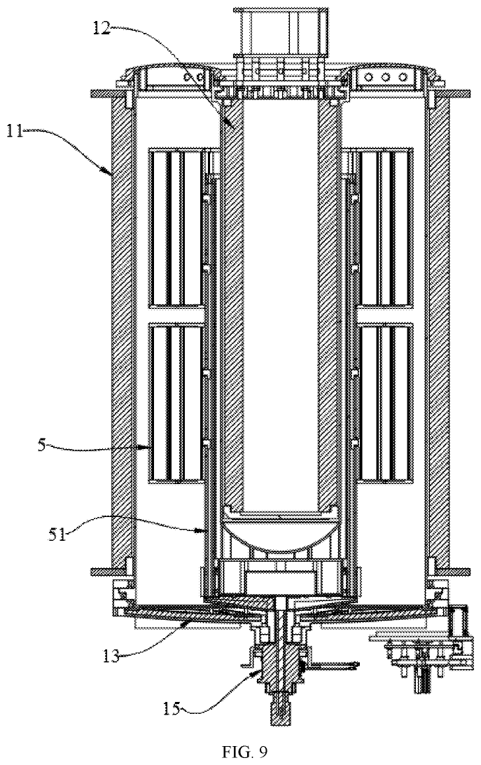

As shown in FIG. 9, each vertical furnace 1 includes an outer furnace 11, an inner furnace 12, and a lower furnace door 13 which define a heating chamber.

Upper ends of the outer furnaces 11 are closed while lower ends thereof are opened; the upper ends of the inner furnaces 12 are opened while the lower ends thereof are closed; and the lower furnace doors 13 are detachably arranged at the lower ends of the outer furnaces 11. Heating sources are arranged on the outer furnaces 11 and the inner furnaces 12, and the heating sources can be heating wires, infrared lamp tubes, electromagnetic induction heating, and the like.

Second boat support frames 51 configured to hang a plurality of vertical boats 5 are arranged in the heating chambers and sleeve outer sides of the inner furnaces 12; a plurality of hanging positions are annularly arranged on the second boat support frames 51; and each hanging position is in clamped connection with a clamping member on the corresponding vertical boat 5.

The vertical furnaces 1 further include seventh drive components 15 which are arranged on the lower furnace doors 13 and connected to the second boat support frames 51. The seventh drive components 15 are configured to drive the second boat support frames 51 to rotate so that silicon wafers borne by the vertical boats 5 can be heated uniformly. The seventh drive components 15 are further sealed with magnetic fluid, thus the second boat support frames 51 and the vertical boats 5 thereon can be driven to rotate while the airtightness of the vertical furnaces 1 is guaranteed.

In the vertical heat treatment device provided by the present invention, the segmented loading and unloading structure is arranged, such that the problem of overlong stroke caused by loading and unloading directly by a single conveying device can be avoided, and the conveying device at each stage is relatively short in conveying stroke, which makes it to complete operations within a relatively short time, thereby reducing the requirement for strength, reducing deformation, as well as helping to increase the utilization rate of device space.

The above are only preferred embodiments of the present invention and are not intended to limit the present invention. Any modifications, equivalent substitutions, and improvements made within the spirit and principle of the present invention should be included within the scope of protection of the present invention.

What is claimed is:

1. A vertical heat treatment device, comprising: a vertical furnace, a temporary storage and cooling portion, and a segmented loading and unloading structure, wherein the segmented loading and unloading structure is provided with a first-stage conveying device and a first-stage conveying device;
the first-stage conveying device is positioned below the vertical furnace and configured to convey a vertical boat into or out of the vertical furnace; and
the first-stage conveying device is configured to transfer the vertical boat between the temporary storage and cooling portion and the first-stage conveying device.

2. The vertical heat treatment device according to claim 1, wherein the first-stage conveying device comprises:
a first horizontal guide rail which is positioned below the vertical furnace, with one end positioned in boat transfer areas of the first-stage conveying device and the first-stage conveying device;
a first supporting component which is slidably arranged on the first horizontal guide rail and configured to support the vertical boat;
a first drive component which is configured to drive the first supporting component to move on the first horizontal guide rail; and
a jacking moving component which is connected to the first horizontal guide rail and configured to drive the first horizontal guide rail and the first supporting component to move in a vertical direction to convey the vertical boat into or out of the vertical furnace.

3. The vertical heat treatment device according to claim 1, wherein the second-stage conveying device comprises:
a first lifting guide rail which is positioned on one side of the vertical furnace, with one end positioned in the boat transfer areas of the second-stage conveying device and the first-stage conveying device;
a first manipulator structure which is slidably arranged on the first lifting guide rail and is provided with a first hanging component and a horizontal moving component, the first hanging component being arranged on the horizontal moving component and configured to hang the vertical boat, and the horizontal moving component being configured to drive the first hanging component to move in a horizontal direction to convey the vertical boat into or out of the temporary storage and cooling portion; and
a second drive component which is configured to drive the first manipulator structure to move on the first lifting guide rail.

4. The vertical heat treatment device according to claim 1, wherein the first-stage conveying device comprises:
a second manipulator structure that is provided with a first-stage conveying component and a second-stage conveying component which are vertically arranged, a boat conveying path of the first-stage conveying component in the vertical direction being at least partially overlapped with the boat conveying path of the second-stage conveying component, the first-stage conveying component and the second-stage conveying component being matched to convey the vertical boat in sections in the vertical direction so as to convey the vertical boat into or out of the vertical furnace; and
a moving platform which is connected to the second-stage conveying component and configured to drive the second-stage conveying component to move in the horizontal direction so as to transfer the vertical boat between the second-stage conveying component and the second-stage conveying device.

5. The vertical heat treatment device according to claim 4, wherein the first-stage conveying component comprises:
a second lifting guide rail which is arranged below the vertical furnace and is positioned on one side of the second-stage conveying component;
a lifting support frame which is slidably arranged on the second lifting guide rail;
a second horizontal guide rail which is arranged on the lifting support frame;
a second support component which is slidably arranged on the second horizontal guide rail and configured to support the vertical boat;
a third drive component which is configured to drive the lifting support frame to move on the second lifting guide rail to convey the vertical boat into or out of the vertical furnace; and
a fourth drive component which is configured to drive the second support component to move on the second horizontal guide rail so as to bear the vertical boat on the second-stage conveying component or transfer the vertical boat to the second-stage conveying component.

6. The vertical heat treatment device according to claim 1, wherein the second-stage conveying component comprises:
a third lifting guide rail which is arranged below the vertical furnace and is lower than the second lifting guide rail in the vertical direction;
a second hanging component which is slidably arranged on the third lifting guide rail and configured to hang the vertical boat; and
a fifth drive component which is configured to drive the second hanging component to move on the third lifting guide rail.

7. The vertical heat treatment device according to claim 6, wherein the second-stage conveying device comprises a boat-in conveying channel and a boat-out conveying channel which are arranged in parallel and are opposite in conveying directions, and part of the conveying paths of the boat-in conveying channel and the boat-out conveying channel correspond to the temporary storage and cooling portion;
the moving platform is arranged between the boat-in conveying channel and the boat-out conveying channel and is configured to drive the second-stage conveying component to move in the horizontal direction so as to transfer the vertical boat among the second-stage conveying component, the boat-in conveying channel, and the boat-out conveying channel.

8. The vertical heat treatment device according to claim 1, wherein the vertical furnace comprises an outer furnace body, an inner furnace body, and a lower furnace door which define a heating chamber; and a boat support frame for hanging a plurality of vertical boats is arranged in the heating chamber.

9. The vertical heat treatment device according to claim 8, wherein the vertical furnace further comprises a rotary chuck and a sixth drive component which are arranged on the lower furnace door, and the sixth drive component is connected to the rotary chuck and configured to drive the whole vertical furnace to rotate so as to make part of hanging positions on the boat support frame corresponding to the first-stage conveying device.

10. The vertical heat treatment device according to claim 1, wherein the segmented loading and unloading structure is capable of conveying two vertical boats each time.
